(19) United States
(12) Patent Application Publication
(10) Pub. No.: US 2013/0026112 A1
(43) Pub. Date: Jan. 31, 2013

(54) FOLDABLE BRACKET FOR EMPLACING A TABLET PERSONAL COMPUTER AND AN AUDIO DEVICE

(71) Applicant: Shao-Chieh TING, Banchiau City (TW)

(72) Inventor: Shao-Chieh TING, Banchiau City (TW)

(21) Appl. No.: 13/189,967

(22) Filed: Jul. 25, 2011

(51) Int. Cl. H05K 7/00

(52) U.S. Cl. 211/26

(57) ABSTRACT

The present invention discloses a foldable bracket for emplacing a tablet personal computer and an audio device. Two front brackets are provided with plural symmetric slots and can provide for emplacing uprightly or obliquely tablet personal computers of various sizes and thicknesses after being opened by rotation. Two rear brackets are provided with symmetric and polyhedral slots and can provide for emplacing a polyhedral barrel-shaped audio device after being opened by rotation. The foldable bracket is formed by sheathing together four small brackets through pivots and shaft holes, constituting three rotatable axes. The audio is a polyhedral barrel and can stand up stably on a desktop.

### BACKGROUND OF THE INVENTION

a) Field of the Invention

The present invention relates to a foldable bracket for emplacing a tablet personal computer and an audio device, and more particularly to a bracket which provides for a tablet personal computer to be emplaced uprightly or obliquely in a horizontal or vertical direction to facilitate reading or touching a screen for control by a user. In addition, the bracket is smaller after folding, which facilitates receiving and carrying.

b) Description of the Prior Art

As development of technologies, one must pursue a small size and light weight for the tablet personal computer so that the user can carry it conveniently. However, when the tablet personal computer is getting smaller, the user convenience in operation will be limited in someway.

Accordingly, a lot of bases for the tablet personal computers arise in markets to facilitate operation and utilization by the user. Nevertheless, all the bases for the tablet personal computers sold on existing markets are not equipped with audio devices and as an audio effect built into the tablet personal computer is limited, it is unable to satisfy the user's request, which is indeed a pity.

Moreover, the bases for the tablet personal computers in the markets are larger in size and therefore are inconvenient in receiving and carrying by the users.

Accordingly, a foldable bracket for emplacing a tablet personal computer and an audio device is provided by the present inventor to solve the aforementioned problem, thereby improving the audio effect of the tablet personal computer and facilitating receiving and carrying by the users.

### SUMMARY OF THE INVENTION

The primary object of the present invention is to provide a foldable bracket for emplacing a tablet personal computer and an audio device, including primarily plural small brackets and a polyhedral barrel-shaped audio device.

A second object of the present invention is to provide a foldable bracket for emplacing a tablet personal computer and an audio device, wherein through slots on the foldable bracket, the tablet personal computer can be emplaced uprightly or obliquely on front brackets to facilitate reading and touching a screen for control by the user, when the bracket is unfolded for use. Furthermore, the polyhedral barrel-shaped audio device can be emplaced on rear brackets and can stand up stably on a desktop after folding the bracket.

A third object of the present invention is to provide a foldable bracket for emplacing a tablet personal computer and an audio device, wherein the bracket is formed by sheathing and assembling each small bracket, which is easy and simple. Moreover, as the size is smaller after closing by rotation, it is easy to receive and carry.

A fourth object of the present invention is to provide a foldable bracket for emplacing a tablet personal computer and an audio device, wherein through a fixed angle at the rear brackets and a change of angle at which the front brackets are opened by rotation, the present invention can be applied in many kinds of tablet personal computers of various sizes and thicknesses.

A fifth object of the present invention is to provide a foldable bracket for emplacing a tablet personal computer and an audio device, wherein when the tablet personal computer is in use, the user can also use a data transmission wire to transmit data or to recharge.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1A shows a three-dimensional schematic view of the present invention which is closed by rotation.

FIG. 1B shows a schematic view of packaging of the present invention.

FIG. 2 shows a three-dimensional schematic view of the present invention which is opened by rotation.

FIGS. 3A and 3B show three-dimensional exploded views of the present invention.

FIGS. 4A and 4B show schematic views of an angle at which the present invention is opened by rotation.

FIG. 5 shows a cutaway schematic view of a sheathing structure of the present invention.

FIG. 5A shows a local blow-up diagram of the sheathing structure in FIG. 5, according to the present invention.

FIGS. 6A and 6B show three-dimensional schematic views of another embodiment of the present invention which is opened and closed.

FIGS. 7A to 7D show three-dimensional views of emplacement of a tablet personal computer, according to the present invention.

### DETAILED DESCRIPTION OF THE PREFERRED EMBODIMENTS

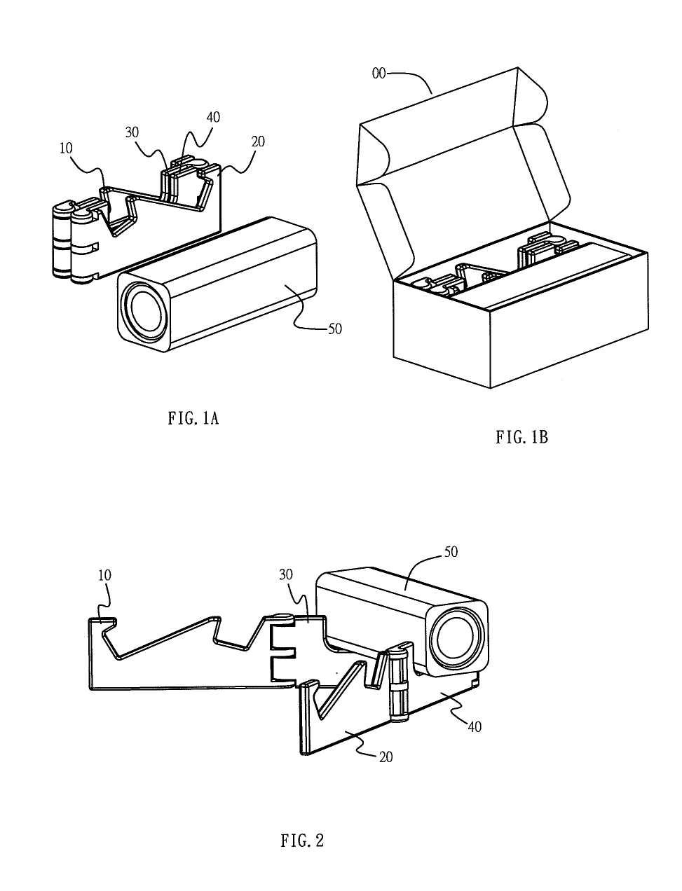

Referring to FIG. 1A and FIG. 2, it shows three-dimensional schematic views of a foldable bracket of the present invention which is closed and opened. As shown in the drawings, the present invention comprises front brackets 10, 20, rear brackets 30, 40 and a polyhedral barrel-shaped audio device 50 which is emplaced on the rear brackets 30, 40.

Referring to FIG. 1B, it shows a schematic view of a foldable bracket for emplacing a tablet personal computer and an audio device, which is emplaced in a box packaging 00. As the size is smaller after folding the bracket, the corresponding box packaging is also smaller, which saves the packaging material and reduces the cost of transportation.

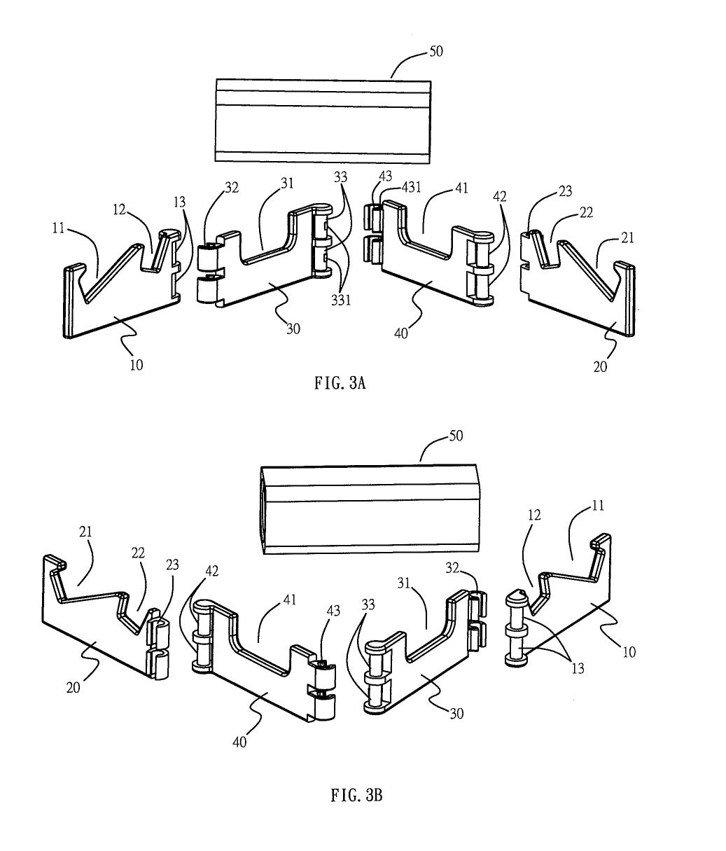

Referring to FIG. 3A and FIG. 3B at a same time, it shows three-dimensional exploded views of the present invention. The front brackets 10, 20 are used to emplace a tablet personal computer and are provided respectively with slots 11, 21 for emplacing obliquely the tablet personal computer and slots 12, 22 for emplacing uprightly the tablet personal computer. The front bracket 10 is provided with plural pivots 13 which sheath with shaft holes 32 on the rear bracket 30; whereas, the front bracket 20 is provided with plural shaft holes 23 which sheath with pivots 42 on the rear bracket 40. Through the abovementioned sheathing, the front brackets can be opened and closed by rotation. When the angle of rotation changes from small to large, the spacing between the slots (slots 11, 21 for oblique emplacement and slots 12, 22 for upright emplacement) changes from large to small; therefore, the tablet personal computer to be emplaced also changes from thick to thin.

The rear brackets 30, 40 are used to emplace the polyhedral barrel-shaped audio device 50 and to sheath with the front brackets 10, 20, increasing the length of use of the bracket and therefore facilitating the tablet personal computer to be stably emplaced obliquely or uprightly. The rear bracket 30 is provided with a slot 31 for emplacing the audio device, plural shaft holes 32 for sheathing with the pivots 13 on the front bracket 10, plural pivots 33 for sheathing with the shaft holes 43 on the rear bracket 40, and positioning bumps 331. On the other hand, the rear bracket 40 is provided with a slot 41 for emplacing polyhedral barrel-shaped the audio device 50, plural pivots 42 for sheathing with the shaft holes 23 on the front bracket 20, plural shaft holes 43 for sheathing with the pivots 33 on the rear bracket 30, and positioning grooves 431 fitting with the positioning bumps 331 on the rear bracket 30 to limit the angle of rotation of the rear brackets. After the rear brackets have been opened by rotation to a defined angle, a polyhedral barrel-shaped audio device can be emplaced.

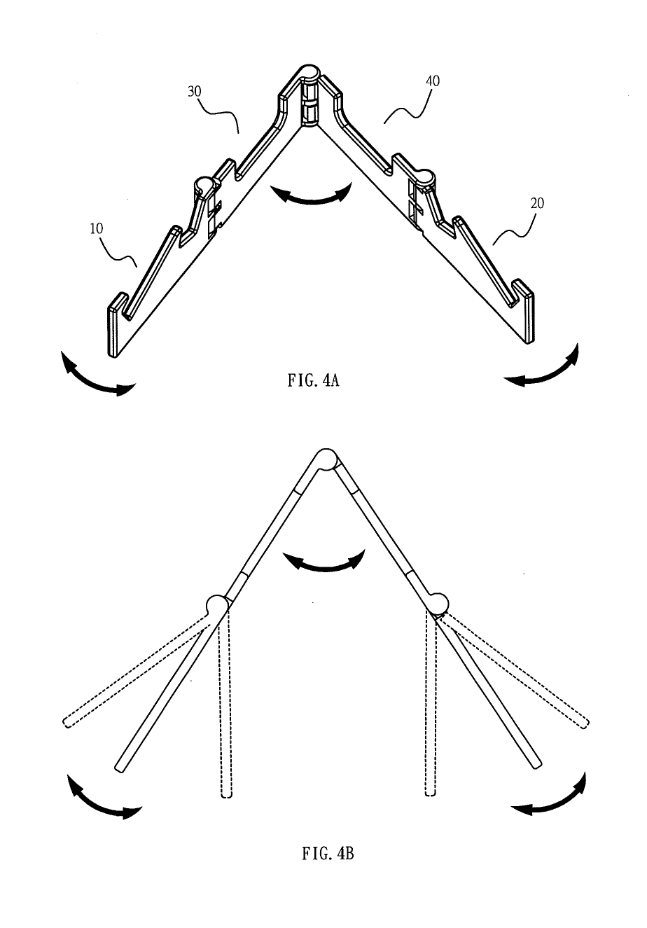

Referring to FIG. 4A and FIG. 4B, it shows schematic views of the foldable bracket of the present invention, which is opened and closed by rotation. The rear brackets 30, 40 cannot rotate again after being opened by rotation to a defined angle, whereas the front brackets 10, 20 can rotate at many angles for applying to the tablet personal computers of various thicknesses and sizes. As the foldable bracket is provided with a proper height, when the tablet personal computer is emplaced uprightly or obliquely, a data transmission wire can be used for transmitting data or recharging without affecting the use as the data transmission wire.

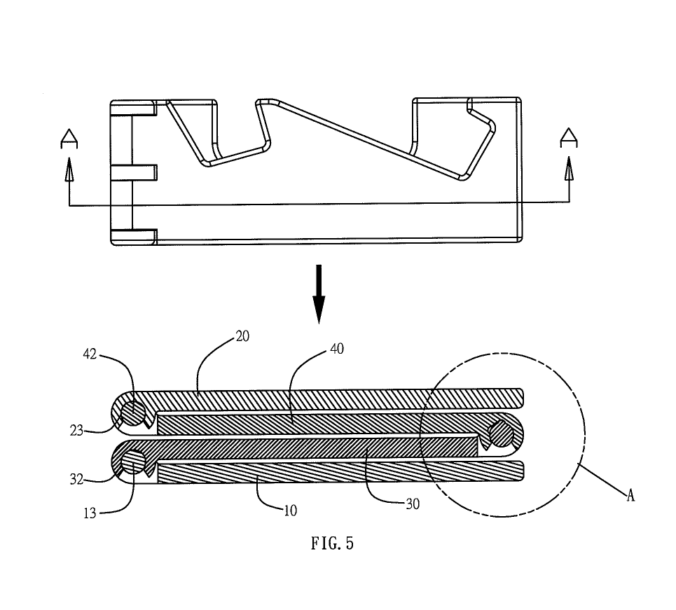

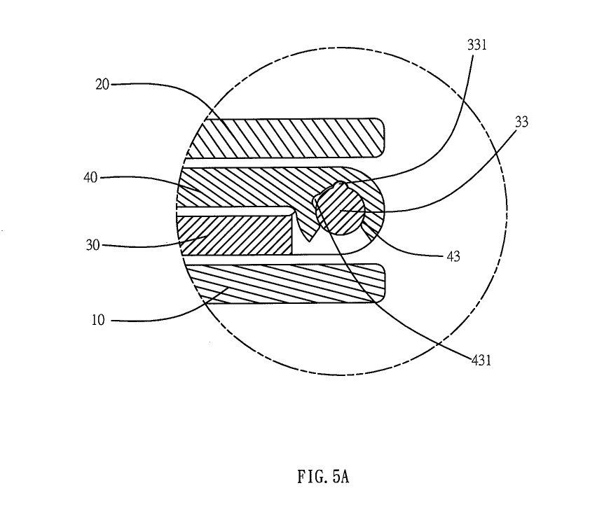

Referring to FIG. 5 which shows a cutaway schematic view of four small brackets of the present invention, sheathing with each other and also referring to FIG. 5A (a local blow-up diagram) at a same time, the angle of use is limited for the two rear brackets 30, 40 through the positioning bumps 331 and the positioning grooves 431, whereas the angle of rotation for the front brackets 10, 20 is not limited.

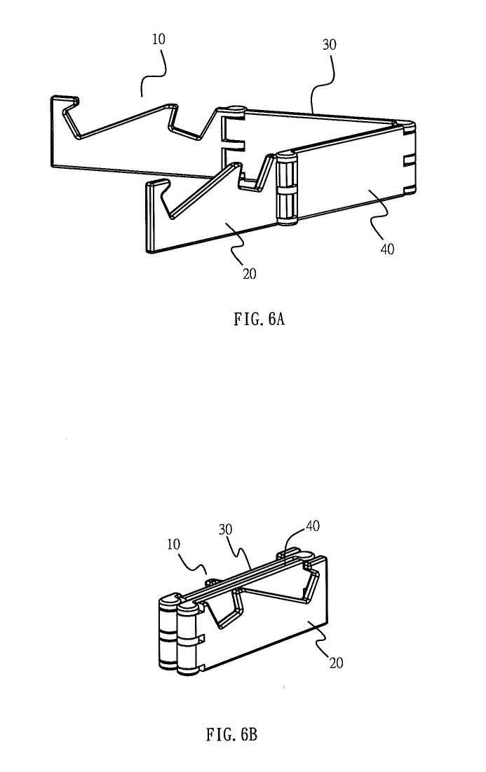

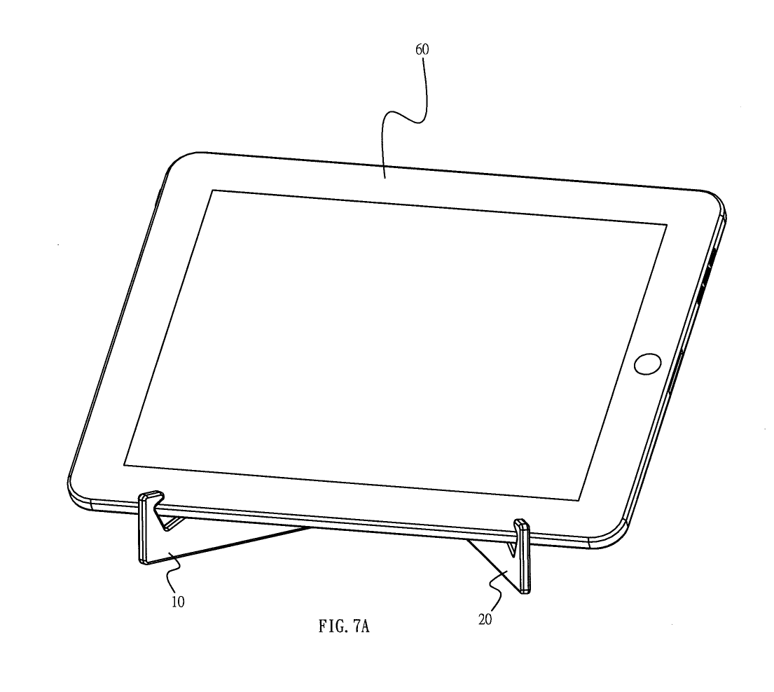

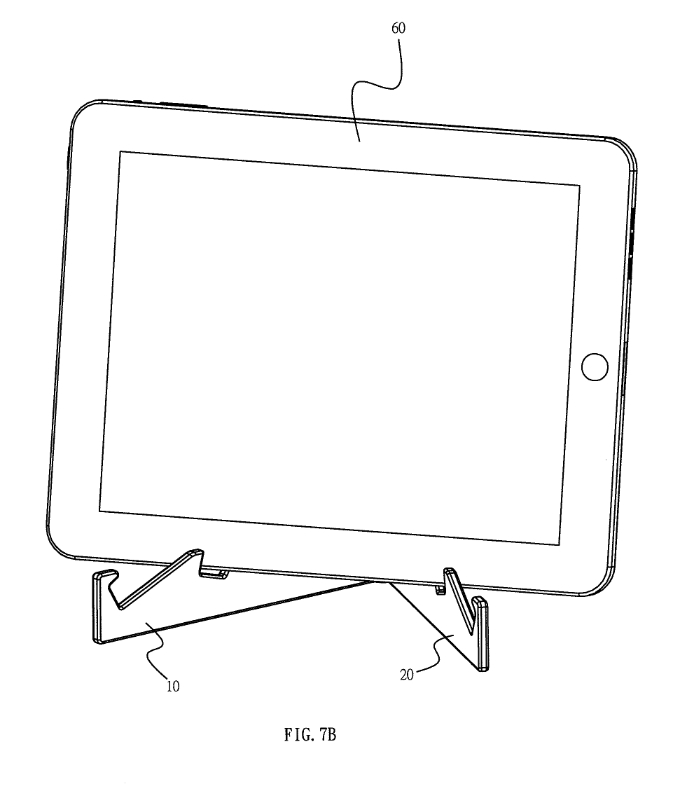

Referring to FIG. 6A and FIG. 6B, it shows that the structure of present invention can be also applied to a foldable bracket where the rear brackets are not provided with the slots for emplacing the polyhedral barrel-shaped audio device. This kind of bracket also uses the structure of four small brackets and the size is smaller after closing by rotation, facilitating the user to carry when going out.

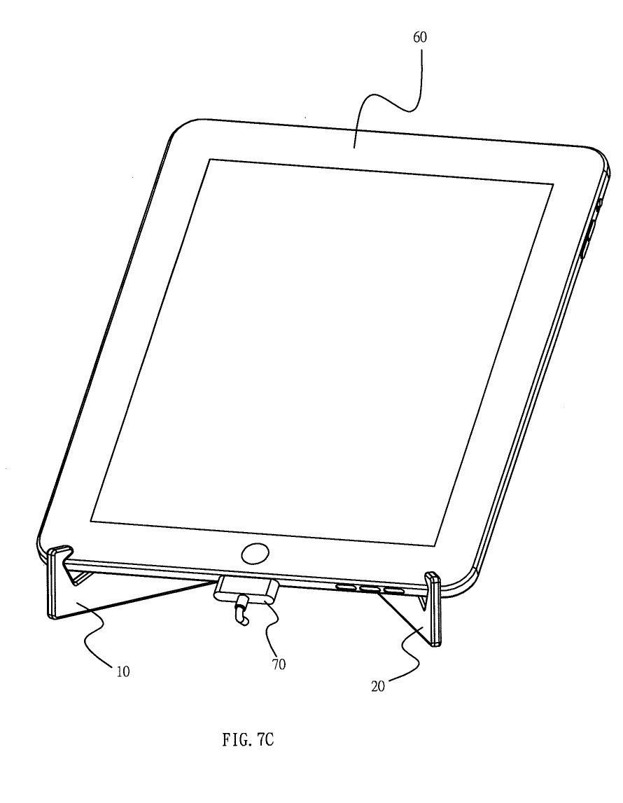

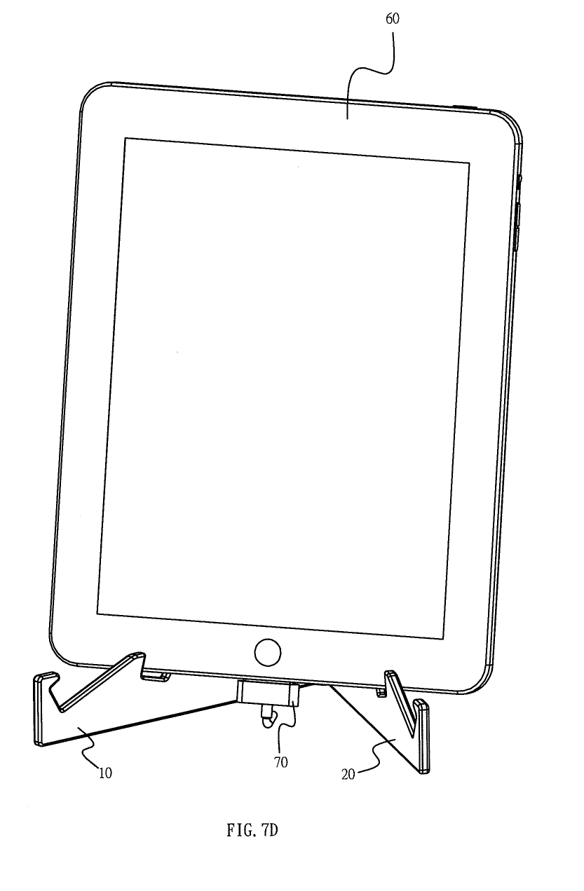

Referring to FIGS. 7A to 7D, it shows schematic views of the tablet personal computer 60 that is emplaced obliquely or uprightly, according to the present invention.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A foldable bracket for emplacing a tablet personal computer and an audio device, comprising:
two symmetric front brackets which are provided with plural symmetric slots for emplacing a tablet personal computer;
two symmetric rear brackets which are provided with plural symmetric slots for increasing a length of use of the bracket and for emplacing a polyhedral barrel-shaped audio device; and
the polyhedral barrel-shaped audio device which is emplaced on the rear brackets to improve an audio effect of the tablet personal computer.

2. The foldable bracket for emplacing a tablet personal computer and an audio device, according to claim 1, wherein the front brackets are provided with plural slots for emplacing obliquely or uprightly the tablet personal computer and the rear brackets are provided with plural slots for emplacing the polyhedral barrel-shaped audio device.

3. The foldable bracket for emplacing a tablet personal computer and an audio device, according to claim 1, wherein the bracket is formed by sheathing and assembling each small bracket through pivots and shaft holes, the bracket is smaller when being folded and the polyhedral barrel-shaped audio device stands up stably on a desktop, facilitating receiving and carrying the bracket.

4. The foldable bracket for emplacing a tablet personal computer and an audio device, according to claim 1, wherein when the rear brackets are opened by rotation to a defined angle, the barrel-shaped audio device is emplaced; the front brackets are opened by rotation due to a change of angle, thereby applying the tablet personal computers of various thicknesses and sizes.

5. The foldable bracket for emplacing a tablet personal computer and an audio device, according to claim 1, wherein when the tablet personal computer is emplaced obliquely or uprightly, the use of a data transmission wire is not affected.
